(19) United States
(12) Patent Application Publication
(10) Pub. No.: US 2009/0029545 A1
(43) Pub. Date: Jan. 29, 2009

(54) METHOD OF MANUFACTURING SEMICONDUCTOR DEVICE

(75) Inventor: Naoki Torazawa, Osaka (JP)

Correspondence Address: STEPTOE & JOHNSON LLP, 1330 CONNECTICUT AVE., NW, WASHINGTON, DC, 20036, US

(73) Assignee: Matsushita Electric Industrial, Kadoma-shi (JP)

(21) Appl. No.: 12/176,614

(22) Filed: Jul. 21, 2008

(30) Foreign Application Priority Data
Jul. 23, 2007 (JP) 2007-190274

(51) Int. Cl. H01L 21/768

(52) U.S. Cl. 438/653; 257/E21.584

(57) ABSTRACT

The present invention provides a method of manufacturing a semiconductor device which method enables a reduction in via resistance. The method of manufacturing the semiconductor device includes the steps of removing a barrier metal film from a bottom surface of a via, with the barrier metal film remaining on a bottom surface of a trench, modifying lower wiring exposed from the bottom surface of the via to form a modified layer, removing the modified layer to form an engraving (recess portion), and depositing a copper film in the engraving, the via, and the trench to form upper wiring and a via plug.

### FIELD OF THE INVENTION

The present invention relates to a method of manufacturing a semiconductor device having wiring formed by a dual damascene method.

### BACKGROUND OF THE INVENTION

Most recent semiconductor integrated circuits have wiring of a multilayer structure in order to deal with the increased degree of integration and a reduced chip size. Furthermore, an increasing number of recent semiconductor integrated circuits use copper (Cu) wiring in order to prevent a possible delay in signal propagation.

A dual damascene method is a technique for forming such Cu wiring of a multilayer structure. The dual damascene method will be described in brief. First, an insulating film is formed on lower wiring. A wiring groove (trench) for upper wiring and a connection hole (via) for a via plug are formed on the insulating film: the connection hole connects the upper wiring and the lower wiring together. A barrier metal film is subsequently formed on a bottom surface and side surfaces of the via and a bottom surface and side surfaces of the trench. A copper (Cu) seed layer is subsequently formed on the barrier metal film. A copper (Cu) film is then deposited in the via and the trench. The Cu film deposited in the via forms the via plug, and the Cu film deposited in the trench forms the upper wiring. The barrier metal film is provided in order to prevent possible diffusion of copper atoms into an oxide film. A material for the barrier metal film is generally a conductive barrier film made up of tungsten nitride (WN), tantalum nitride (TaN), or titanium nitride (TiN).

However, when the wiring is formed by the dual damascene method, the miniaturized wiring and via plugs disadvantageously degrade EM (Electro Migration) resistance and increase via resistance. Factors affecting characteristics such as the EM resistance and the via resistance include the barrier metal film present on the bottom and side surfaces of the Cu wiring.

The barrier metal film on the bottom surface of the via plug most severely affects the characteristics such as the EM resistance and the via resistance. The increased thickness of the barrier metal film may degrade the EM resistance and increase the via resistance. Thus, the barrier metal film on the bottom surface of the via plug needs to be removed.

A conventional method of forming wiring with the barrier metal film removed from the bottom surface of the via plug will be described with reference to FIG. 3. FIG. 3 is a sectional view of a conventional semiconductor device. FIG. 3 shows wiring of a multilayer structure formed by the dual damascene method.

As shown in FIG. 3, the wiring of the multilayer structure formed by the dual damascene method has lower wiring 101 formed on a semiconductor substrate, upper wiring 105 formed above the lower wiring 101, the lower wiring 101 and the upper wiring 105 are connected together via a via plug 104. A barrier metal film 106 is formed on a bottom surface and side surfaces of the upper wiring (trench) 105 and side surfaces of the via plug (via) 104.

The conventional method of forming the wiring will be described in brief. First, the lower wiring 101 is formed on the semiconductor substrate. An insulating barrier film 102 is formed on the lower wiring 101. An interlayer insulating film 103 is formed on the insulating barrier film 102. Then, a via connected to the lower wiring 101 and a trench connected to the via are formed. The barrier metal film 106 is formed over the via and the trench.

To form the barrier metal film 106, film formation is performed such that the ratio (b/a) of the film thickness b of the barrier metal film 106 on the bottom surface of the via to the film thickness a of the barrier metal film 106 on the bottom surface of the trench is at most 60%.

Then, to prevent a possible degradation of EM resistance and a possible increase in via resistance, the barrier metal film 106 is removed from the bottom surface of the via by a dry etching process. At this moment, dry etching is performed such that the ratio of an etching rate for the bottom surface of the trench to an etching rate for the bottom surface of the via is at least 80%.

This dry etching process etches the barrier metal film 106 on the bottom surface of the via and simultaneously etches the barrier metal film 106 on the bottom surface of the trench. However, as described above, the barrier metal film can be left on the bottom surface of the trench by performing film formation such that the film thickness ratio of the barrier metal film on the bottom surface of the via to the barrier metal film on the bottom surface of the trench is at most 60% and performing dry etching such that the etching rate ratio of the bottom surface of the trench to the bottom surface of the via is at least 80%.

After the dry etching process, a Cu seed layer is formed on the via and the trench. A Cu film is deposited in the via and the trench. The Cu film deposited in the via forms the via plug 104. The Cu film deposited in the trench forms the upper wiring 105 (see, for example, Japanese Patent Laid-Open No. 2003-258088).

### DISCLOSURE OF THE INVENTION

As described above, the conventional technique removes the barrier metal film from the bottom surface of the via, with the barrier metal film remaining on the bottom surface of the trench, by performing film formation such that the film thickness ratio of the barrier metal film on the bottom surface of the via to the barrier metal film on the bottom surface of the trench is at most 60% and performing dry etching such that the etching rate ratio of the bottom surface of the trench to the bottom surface of the via is at least 80%.

On the other hand, with the wiring and vias increasingly miniaturized in recent years, the wiring and via plugs have been demanded to offer further reduced resistance. However, the demand cannot be met simply by removing the barrier metal film from the bottom surface of the via.

Thus, the via resistance is expected to be reduced by removing the metal barrier film from the bottom surface of the via and then engraving the lower wiring exposed from the bottom surface. However, with the conventional method, when the engraving is formed, the metal barrier film on the bottom surface of the trench is removed. Thus, disadvantageously, the EM characteristic of the upper wiring is degraded.

In view of the problems, an object of the present invention is to provide a method of manufacturing a semiconductor device which method can remove the metal barrier film from the bottom surface of the via and engrave the lower wiring exposed from the bottom surface of the via, with the metal barrier film remaining on the bottom surface of the trench, thus enabling a reduction in via resistance without degrading the EM resistance of the upper wiring.

To accomplish this object, a method of manufacturing a semiconductor device according to the present invention includes the steps of forming lower wiring on a semiconductor substrate, forming an insulating film on the lower wiring, forming a via and a trench including a barrier metal, in the insulating film, removing the barrier metal from a bottom surface of the via, with the barrier metal remaining on a bottom surface of the trench, modifying the lower wiring exposed from the bottom surface of the via to form a modified layer, removing the modified layer to form a recess portion in the lower wiring, and depositing a copper (Cu) film so as to fill the recess portion, the via and the trench.

Furthermore, the step of forming the via and the trench includes the steps of forming the via in the insulating film, forming the trench in the insulating film, and depositing the barrier metal film over the via and the trench, and a barrier metal film deposition rate ratio of the bottom surface of the trench to the bottom surface of the via is higher than a barrier metal removal rate ratio of the bottom surface of the trench to the bottom surface of the via.

Furthermore, the step of forming the via and the trench includes the steps of forming the trench in the insulating film, depositing the barrier metal film over the trench, removing the barrier metal from a via forming area, forming the via in the via forming area, and depositing the barrier metal film over the via and the trench.

Furthermore, one of a resputtering process and an etching process is used to remove the barrier metal from the via forming area.

Furthermore, argon (Ar) gas is used for the resputtering process.

Furthermore, halogen-containing gas is used for the etching process.

Furthermore, one of a resputtering process and an etching process is used to remove the barrier metal from the bottom surface of the via.

Furthermore, argon (Ar) gas is used for the resputtering process.

Furthermore, halogen-containing gas is used for the etching process.

Furthermore, one of an ion irradiation process, a plasma irradiation process, and an annealing process is used to form the modified layer.

Furthermore, oxygen molecule (O₂) gas is used for the ion irradiation process.

Furthermore, gas generating one of an oxygen atom and a molecule containing the oxygen atom is used for the plasma irradiation process.

Furthermore, the annealing process is carried out in an O₂ gas atmosphere.

Furthermore, to remove the modified layer, a wet etching process is carried out using organic acid containing a fluorine-containing compound.

A method of manufacturing a semiconductor device according to the present invention includes the steps of forming lower wiring on a semiconductor substrate, forming an insulating film on the lower wiring, forming a trench in the insulating film, forming a barrier metal over the trench, removing the barrier metal from a via forming area, forming a via in the via forming area, forming a barrier metal over the via and the trench, removing the barrier metal from a bottom surface of the via and removing a part of the lower wiring exposed from the bottom surface of the via, with the barrier metal remaining on a bottom surface of the trench, and depositing a Cu film so as to fill the removed part of the lower wiring, the via, and the trench.

Furthermore, one of a resputtering process and an etching process is used to remove the barrier metal from the via forming area.

Furthermore, argon (Ar) gas is used for the resputtering process.

Furthermore, halogen-containing gas is used for the etching process.

Furthermore, one of a resputtering process and an etching process is used to remove the barrier metal from the bottom surface of the via and to remove a part of the lower wiring exposed from the bottom surface of the via.

Furthermore, argon (Ar) gas is used for the resputtering process.

Furthermore, halogen-containing gas is used for the etching process.

Thus, with the barrier metal film remaining on the bottom surface of the trench, the metal barrier film can be removed from the bottom surface of the via, and the lower wiring exposed from the bottom surface of the via can be engraved. Therefore, via resistance can be reduced without degrading the EM resistance of the upper wiring.

Furthermore, the lower wiring exposed from the bottom surface of the via is modified, and the modified layer is removed to form the recess portion (engraving) in the lower wiring. This enables a reduction in the roughness of a surface of the lower wiring (a surface of the recess portion) exposed from the bottom surface of the via. Thus, the via plug and the lower wiring can be more tightly contacted with each other, allowing the EM resistance to be enhanced.

Furthermore, after the formation of the via and the trench, during the deposition of the barrier metal film over the via and the trench, the barrier metal film deposition rate ratio of the bottom surface of the trench to the bottom surface of the via is set higher than the barrier metal removal rate ratio of the bottom surface of the trench to the bottom surface of the via. Consequently, the barrier metal can be reliably left on the bottom surface of the trench.

Furthermore, first, the trench is formed, and the barrier metal film is then deposited over the trench. Then, the via is formed, and the barrier metal film is deposited again. Consequently, the barrier metal can be reliably left on the bottom surface of the trench.

As described above, the method of manufacturing a semiconductor device according to the present invention can reduce the via resistance and is thus useful for miniaturized and integrated semiconductor devices.

### BRIEF DESCRIPTION OF THE DRAWINGS

FIG. 1A is a sectional view of a step of a method of manufacturing a semiconductor device according to Embodiment 1 of the present invention;

FIG. 1B is a sectional view of a step of the method of manufacturing the semiconductor device according to Embodiment 1 of the present invention;

FIG. 1C is a sectional view of a step of the method of manufacturing the semiconductor device according to Embodiment 1 of the present invention;

FIG. 1D is a sectional view of a step of the method of manufacturing the semiconductor device according to Embodiment 1 of the present invention;

FIG. 1E is a sectional view of a step of the method of manufacturing the semiconductor device according to Embodiment 1 of the present invention;

FIG. 1F is a sectional view of a step of the method of manufacturing the semiconductor device according to Embodiment 1 of the present invention;

FIG. 1G is a sectional view of a step of the method of manufacturing the semiconductor device according to Embodiment 1 of the present invention;

FIG. 1H is a sectional view of a step of the method of manufacturing the semiconductor device according to Embodiment 1 of the present invention;

FIG. 1I is a sectional view of a step of the method of manufacturing the semiconductor device according to Embodiment 1 of the present invention;

FIG. 1J is a sectional view of a step of the method of manufacturing the semiconductor device according to Embodiment 1 of the present invention;

FIG. 2A is a sectional view of a step of a method of manufacturing a semiconductor device according to Embodiment 2 of the present invention;

FIG. 2B is a sectional view of a step of the method of manufacturing the semiconductor device according to Embodiment 2 of the present invention;

FIG. 2C is a sectional view of a step of the method of manufacturing the semiconductor device according to Embodiment 2 of the present invention;

FIG. 2D is a sectional view of a step of the method of manufacturing the semiconductor device according to Embodiment 2 of the present invention;

FIG. 2E is a sectional view of a step of the method of manufacturing the semiconductor device according to Embodiment 2 of the present invention;

FIG. 2F is a sectional view of a step of the method of manufacturing the semiconductor device according to Embodiment 2 of the present invention;

FIG. 2G is a sectional view of a step of the method of manufacturing the semiconductor device according to Embodiment 2 of the present invention;

FIG. 2H is a sectional view of a step of the method of manufacturing the semiconductor device according to Embodiment 2 of the present invention;

FIG. 2I is a sectional view of a step of the method of manufacturing the semiconductor device according to Embodiment 2 of the present invention;

FIG. 2J is a sectional view of a step of the method of manufacturing the semiconductor device according to Embodiment 2 of the present invention; and

FIG. 3 is a sectional view showing a conventional semiconductor device.

### DESCRIPTION OF THE EMBODIMENTS

### Embodiment 1

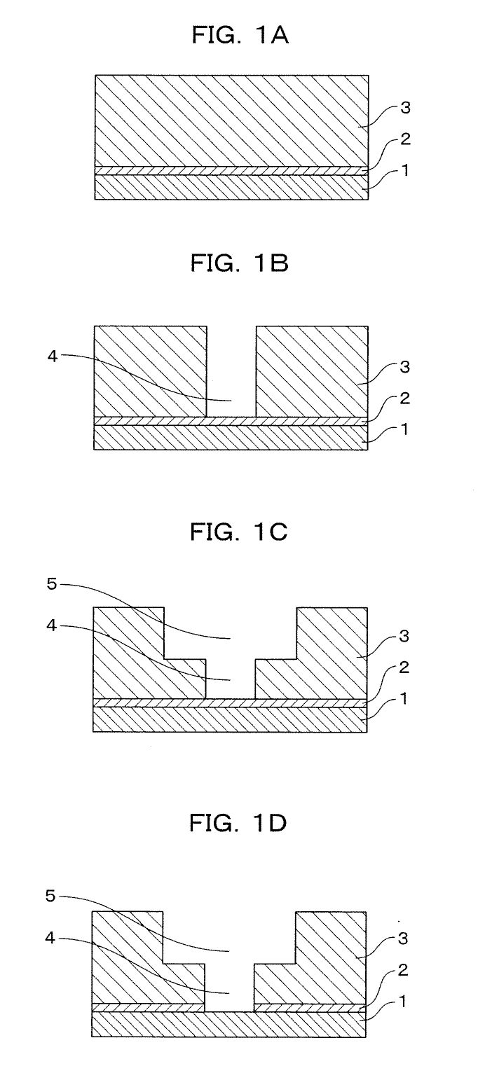

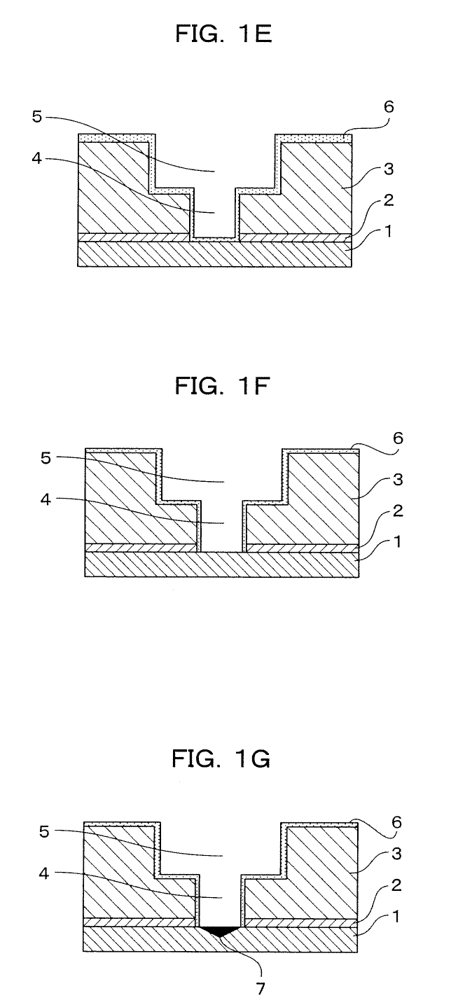

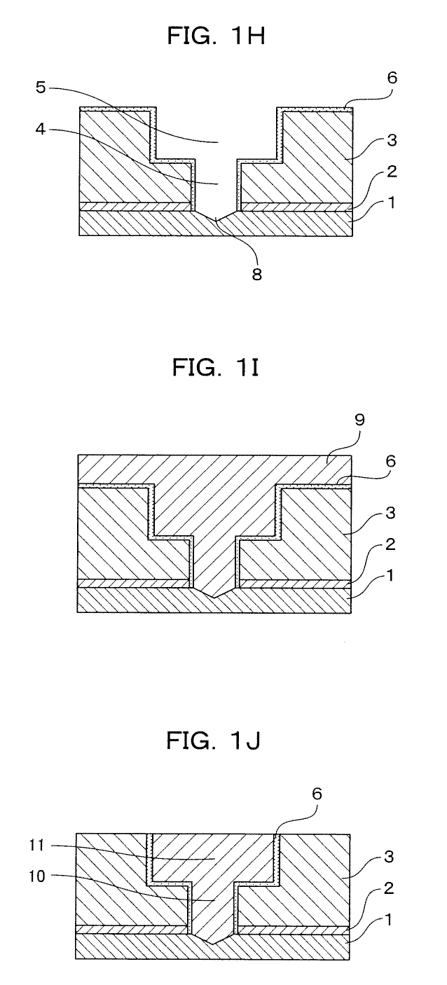

A method of manufacturing a semiconductor device according to Embodiment 1 of the present invention will be described below with reference to FIGS. 1A to 1J. FIGS. 1A to 1J are sectional views showing steps of the method of manufacturing the semiconductor device according to Embodiment 1 of the present invention.

First, as shown in FIG. 1A, lower wiring 1 is formed on a semiconductor substrate with an element such as a transistor formed thereon. Then, an insulating barrier film 2 is formed on the lower wiring 1 by a CVD method. SiCO or SiCN is used as the insulating barrier film 2. Subsequently, an interlayer insulating film 3 is formed on the insulating barrier film 2 by a CVD method. A carbon-containing silicon oxide film (SiOC film) is used as the interlayer insulating film 3.

Then, as shown in FIG. 1B, a photo resist having a via pattern is deposited on the interlayer insulating film 3 by a photolithography method. The interlayer insulating film 3 is subsequently removed by a dry etching process. A via 4 is thus formed so as to connect to the insulating barrier film 2. Carbon fluoride-containing (CF-containing) gas is used as etching gas. Subsequently, the photo resist is removed by ashing.

Then, as shown in FIG. 1C, a photo resist having a trench pattern is deposited on the interlayer insulating film 3 by a photolithography method. The interlayer insulating film 3 is subsequently removed by a dry etching process. A trench 5 is thus formed so as to connect to the via 4. Carbon fluoride-containing (CF-containing) gas is used as etching gas. Subsequently, the photo resist is removed by ashing.

Then, as shown in FIG. 1D, the insulating barrier film 2 at a bottom surface of the via 4 is removed by a dry etching process.

Then, as shown in FIG. 1E, a barrier metal film 6 is deposited over the via 4 and the trench 5 by a sputtering method. Tantalum nitride (TaN), tantalum (Ta), or the like is used as the barrier metal film 6. The barrier metal film 6 deposited by the sputtering method is thickest on a field, thinner on the trench 5 than on the field, and thinnest on the via 4 (a difference in coverage). Sputtering conditions are shown below. For example, the film deposition is performed such that the film thickness on the field is 10 nm.

### Sputtering Conditions

Target power: 20,000 W
Substrate bias power: 230 W
RF-coil power: 0 W
Argon (Ar) flow rate: 20 sccm
Nitrogen (N) flow rate: 80 sccm (for deposition of a TaN film)

Then, as shown in FIG. 1F, the barrier metal film 6 is removed from the bottom surface of the via 4, with the barrier metal film 6 remaining on a bottom surface of the trench 5. Thus, the lower wiring 1 is exposed from the bottom surface of the via 4. The barrier metal film 6 can be removed by a resputtering process using, for example, argon (Ar) gas. The resputtering process allows all of the barrier metal film on the field, the barrier metal film covering the trench 5, and the barrier metal film covering the via 4 to be etched at an almost constant rate. Resputtering conditions are shown below.

### Resputtering Conditions

Target power: 500 W
Substrate bias power: 400 W
RF-coil power: 1,200 W
Ar flow rate: 15 sccm

The resputtering process for about 5 seconds enables the barrier metal film 6 to be removed from the bottom surface of the via 4. At this moment, the barrier metal film 6 of about 2 nm in film thickness remains on the bottom surface of the trench 5.

Then, as shown in FIG. 1G, the lower wiring 1 exposed from the bottom surface of the via 4 is modified to form a modified layer 7. This modifying process can be achieved by an ion irradiation process using, for example, oxygen molecule (O₂) gas. That is, the ion irradiation oxidizes a copper (Cu) film in the lower wiring 1 to form the modified layer 7 of CuOx on a surface of the lower wiring 1. The depth of the ion irradiation can be controlled by appropriately setting RF bias and pressure. Here, the depth of the ion irradiation is controlled to about 30 nm.

Then, as shown in FIG. 1H, the modified layer 7, formed in the lower wiring 1, is removed by a wet etching process. Thus, an engraving (recess portion) 8 is formed in the lower wiring 1. Organic acid containing a fluorine-containing compound is used for the wet etching process. In this case, since the etching rate of the CuOx film is generally higher than that of the Cu film, only the CuOx film is selectively removed.

Then, as shown in FIG. 1I, a copper (Cu) seed layer is formed on surfaces of the engraving 8, the via 4, and the trench 5 by a sputtering method. A Cu film 9 is then deposited by an electroplating method so as to fill the engraving 8, the via 4, and the trench 5.

Then, as shown in FIG. 1J, surplus parts of the Cu film 9 and barrier metal film 6 sticking out from the trench 5 are polished by a CMP method. Consequently, the interlayer insulating film 3 is exposed from a portion except for the area of the trench 5, with the Cu film 9 remaining in the engraving 8, the via 4, and the trench 5. The Cu film 9 in the via 4 and the engraving 8 forms a via plug 10. The Cu film 9 in the trench 5 forms upper wiring 11.

According to Embodiment 1, with the barrier metal film remaining on the bottom surface of the trench, the barrier metal film can be removed from the bottom surface of the via, and the engraving (recess portion) with a less rough surface can be formed in the lower wiring exposed from the bottom surface of the via. Embodiment 1 thus enables enhancement of the EM resistance of the via and a reduction in via resistance without degrading the EM resistance of the upper wiring.

Furthermore, the sputtering process is used to deposit the barrier metal film, and the resputtering process is used to remove the barrier metal from the bottom surface of the via. Thus, the barrier metal film deposition rate ratio of the bottom surface of the trench to the bottom surface of the via can be set higher than the barrier metal removal rate ratio of the bottom surface of the trench to the bottom surface of the via. Consequently, the barrier metal film can be reliably left on the bottom surface of the trench.

With the conventional technique, after the barrier metal is removed from the bottom surface of the via, the barrier metal film is deposited again in order to protect the bottom surface of the trench. In contrast, according to Embodiment 1, the barrier metal film remains on the bottom surface of the trench. This eliminates the need to deposit the barrier metal film again, enabling a reduction in the number of steps required.

In Embodiment 1, the resputtering process is used to remove the barrier metal film from the bottom surface of the via. However, an etching process may be used. Halogen-containing gas such as boron chloride (BCl₃) is used for the etching process. However, to reliably leave the barrier metal film on the bottom surface of the trench, the etching needs to be performed such that the barrier metal film deposition rate ratio of the bottom surface of the trench to the bottom surface of the via is higher than the barrier metal removal rate ratio of the bottom surface of the trench to the bottom surface of the via as described above.

Furthermore, the ion irradiation process is used to form the modified layer. However, a plasma irradiation process or an annealing process may be used. Gas generating an oxygen atom or molecules containing an oxygen atom is used for the plasma irradiation process. The annealing process is carried out in an O₂ gas atmosphere. The plasma irradiation process or the annealing process oxidizes the Cu film in the lower wiring to form a CuOx film.

### Embodiment 2

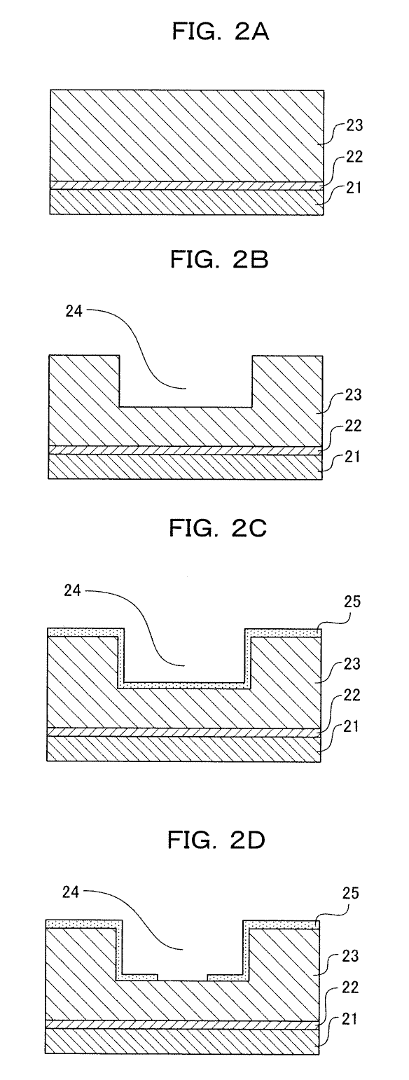

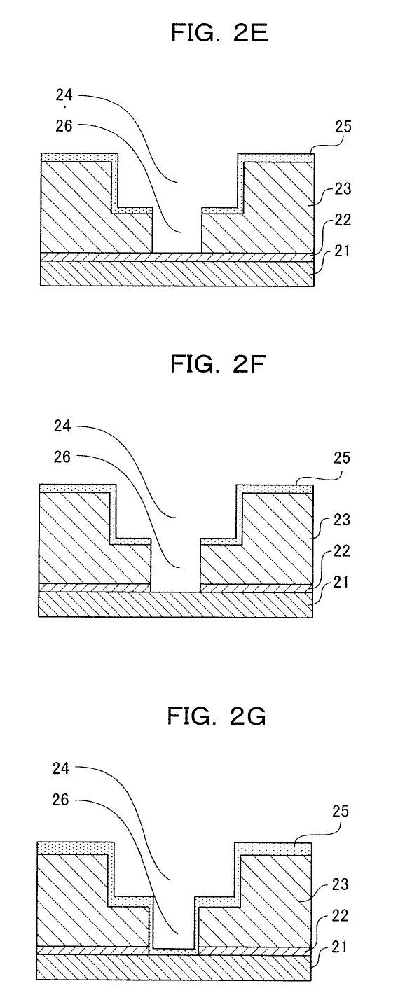

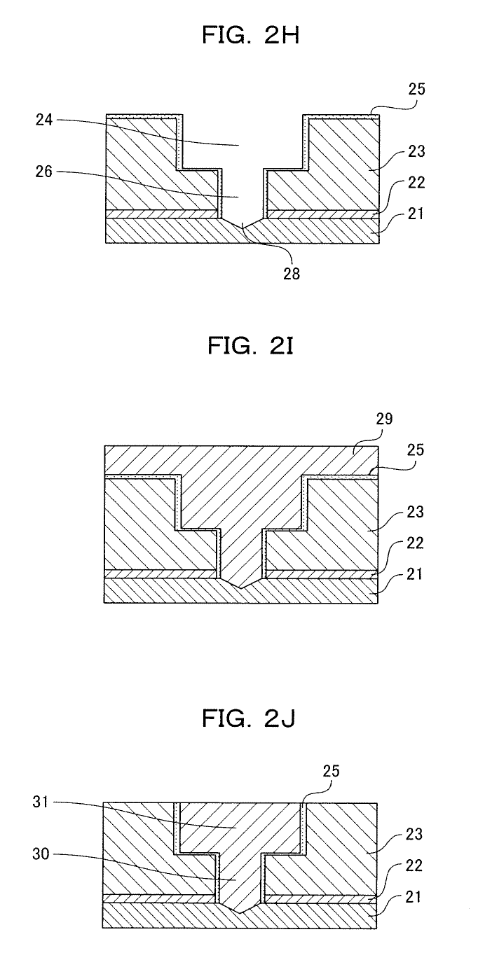

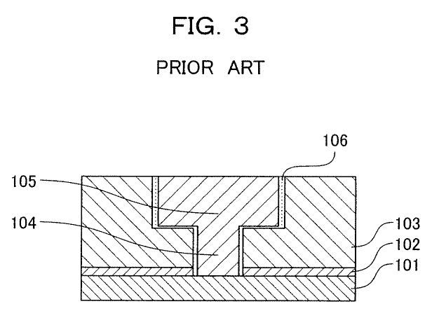

A method of manufacturing a semiconductor device according to Embodiment 2 of the present invention will be described below with reference to FIGS. 2A to 2J. FIGS. 2A to 2J are sectional views showing steps of the method of manufacturing the semiconductor device according to Embodiment 2 of the present invention.

First, as shown in FIG. 2A, lower wiring 21 is formed on a semiconductor substrate with an element such as a transistor formed thereon. Then, an insulating barrier film 22 is formed on the lower wiring 21 by a CVD method. SiCO or SiCN is used as the insulating barrier film 22. Subsequently, an interlayer insulating film 23 is formed on the insulating barrier film 22 by a CVD method. A carbon-containing silicon oxide film (SiOC film) is used as the interlayer insulating film 23.

Then, as shown in FIG. 2B, a photo resist having a trench pattern is deposited on the interlayer insulating film 23 by a photolithography method. The interlayer insulating film 23 is subsequently removed by a dry etching process. A trench 24 is thus formed in an upper part of the interlayer insulating film 23. Subsequently, the photo resist is removed by ashing.

Then, as shown in FIG. 2C, a barrier metal film 25 is deposited over the trench 24 by a sputtering method. Tantalum nitride (TaN), tantalum (Ta), or the like is used as the barrier metal film 25. Sputtering conditions are shown below. For example, the film deposition is performed such that the film thickness on a field is about 5 to 10 nm.

### Sputtering Conditions

Target power: 20,000 W
Substrate bias power: 230 W
RF-coil power: 0 W
Argon (Ar) flow rate: 20 sccm
Nitrogen (N) flow rate: 80 sccm (for deposition of a TaN film)

Then, as shown in FIG. 2D, a photo resist having a via pattern is deposited on the barrier metal film 25 by a photolithography method. Subsequently, the barrier metal film 25 is removed from a via forming area by a dry etching process. Halogen-containing gas such as boron chloride (BCl₃) is used as etching gas.

Subsequently, as shown in FIG. 2E, the interlayer insulating film 23 is removed by a dry etching process. A via 26 is thus formed in the via forming area so as to connect to the insulating barrier film 22. Carbon fluoride-containing (CF-containing) gas is used as etching gas. The photo resist is subsequently removed by ashing.

Then, as shown in FIG. 2F, the insulating barrier film 22 is removed from a bottom surface of the via 26 by a dry etching process.

Then, as shown in FIG. 2G, the barrier metal film 25 is deposited over the via 26 and the trench 24 by a sputtering method. Sputtering conditions are shown below. For example, the film deposition is performed such that the film thickness on the field is about 5 nm.

### Sputtering Conditions

Target power: 20,000 W
Substrate bias power: 230 W
RF-coil power: 0 W
Argon (Ar) flow rate: 20 sccm
Nitrogen (N) flow rate: 80 sccm (for deposition of a TaN film)

Thus, the barrier metal is deposited in the via 26. Furthermore, the barrier metal is deposited in the trench 24 again.

Then, as shown in FIG. 2H, the barrier metal film 25 is removed from the bottom surface of the via 26 by a resputtering process, with the barrier metal film 25 remaining on a bottom surface of the trench 24. Furthermore, an engraving (recess portion) 28 is formed in the lower wiring 21 exposed from the bottom surface of the via 26 by the resputtering process. Argon (Ar) gas is used for the resputtering process. Resputtering conditions are shown below.

### Resputtering Conditions

Target power: 500 W
Substrate bias power: 400 W
RF-coil power: 1,200 W
Ar flow rate: 15 sccm

The resputtering process for about 3 seconds enables the barrier metal film 25 to be removed from the bottom surface of the via 26. The subsequent resputtering process for about 4 seconds enables the engraving 28 of about 30 nm in depth to be formed. At this moment, the barrier metal film 25 of about 2 to 7 nm in film thickness remains on the bottom surface of the trench 24.

Then, as shown in FIG. 2I, a copper (Cu) seed layer is formed on surfaces of the engraving 28, the via 26, and the trench 24 by a sputtering method. A copper (Cu) film 29 is then deposited by an electroplating method so as to fill the engraving 28, the via 26, and the trench 24.

Then, as shown in FIG. 2J, surplus parts of the Cu film 29 and barrier metal film 25 sticking out from the trench 24 are polished by a CMP method. Consequently, the interlayer insulating film 23 is exposed from a portion except for the area of the trench 24, with the Cu film 29 remaining in the engraving 28, the via 26, and the trench 24. The Cu film 29 in the via 26 and the engraving 28 forms a via plug 30. The Cu film 29 in the trench 24 forms upper wiring 31.

According to Embodiment 2, with the barrier metal film remaining on the bottom surface of the trench, the barrier metal film can be removed from the bottom surface of the via, and the engraving (recess portion) can be formed in the lower wiring exposed from the bottom surface of the via. Consequently, the via resistance can be reduced without degrading the EM resistance of the upper wiring.

Furthermore, first, the trench is formed, and the barrier metal is then deposited over the trench. Then, the via is formed, and the barrier metal is deposited again. Thus, the barrier metal film can be more reliably left on the bottom surface of the trench by adjusting the difference in film thickness between the barrier metal film formed on the bottom surface of the trench and the barrier metal film formed on the bottom surface of the via.

In Embodiment 2, the etching process is used to remove the barrier metal film from the bottom surface of the trench. However, a resputtering process may be used. Ar gas is used for the resputtering process.

Furthermore, the resputtering process is used to remove the barrier metal film from the bottom surface of the via. However, an etching process may be used. Halogen-containing gas such as boron chloride (BCl₃) is used for the etching process.

Additionally, the resputtering process is used to form the engraving. However, the modifying process may be used as is the case with Embodiment 1.

What is claimed is:

1. A method of manufacturing a semiconductor device, comprising the steps of:
forming lower wiring on a semiconductor substrate;
forming an insulating film on the lower wiring;
forming a via and a trench comprising a barrier metal, in the insulating film;
removing the barrier metal from a bottom surface of the via, with the barrier metal remaining on a bottom surface of the trench;
modifying the lower wiring exposed from the bottom surface of the via to form a modified layer;
removing the modified layer to form a recess portion in the lower wiring; and
depositing a copper film so as to fill the recess portion, the via and the trench.

2. The method of manufacturing the semiconductor device according to claim 1, wherein the step of forming the via and the trench comprises the steps of:
forming the via in the insulating film;
forming the trench in the insulating film; and
depositing the barrier metal film over the via and the trench,
wherein a barrier metal film deposition rate ratio of the bottom surface of the trench to the bottom surface of the via is higher than a barrier metal removal rate ratio of the bottom surface of the trench to the bottom surface of the via.

3. The method of manufacturing the semiconductor device according to claim 1, wherein the step of forming the via and the trench comprises the steps of:
forming the trench in the insulating film;
depositing the barrier metal film over the trench;
removing the barrier metal from a via forming area;
forming the via in the via forming area; and
depositing the barrier metal film over the via and the trench.

4. The method of manufacturing the semiconductor device according to claim 3, wherein one of a resputtering process and an etching process is used to remove the barrier metal from the via forming area.

5. The method of manufacturing the semiconductor device according to claim 4, wherein argon gas is used for the resputtering process.

6. The method of manufacturing the semiconductor device according to claim 4, wherein halogen-containing gas is used for the etching process.

7. The method of manufacturing the semiconductor device according to claim 1, wherein one of a resputtering process and an etching process is used to remove the barrier metal from the bottom surface of the via.

8. The method of manufacturing the semiconductor device according to claim 7, wherein argon gas is used for the resputtering process.

9. The method of manufacturing the semiconductor device according to claim 7, wherein halogen-containing gas is used for the etching process.

10. The method of manufacturing the semiconductor device according to claim 1, wherein one of an ion irradiation process, a plasma irradiation process, and an annealing process is used to form the modified layer.

11. The method of manufacturing the semiconductor device according to claim 10, wherein oxygen molecule gas is used for the ion irradiation process.

12. The method of manufacturing the semiconductor device according to claim 10, wherein gas generating one of an oxygen atom and a molecule containing the oxygen atom is used for the plasma irradiation process.

13. The method of manufacturing the semiconductor device according to claim 10, wherein the annealing process is carried out in an O₂ gas atmosphere.

14. The method of manufacturing the semiconductor device according to claim 1, wherein to remove the modified layer, a wet etching process is carried out using organic acid containing a fluorine-containing compound.

15. A method of manufacturing a semiconductor process, comprising the steps of:
forming lower wiring on a semiconductor substrate;
forming an insulating film on the lower wiring;
forming a trench in the insulating film;
forming a barrier metal over the trench;
removing the barrier metal from a via forming area;
forming a via in the via forming area;
depositing a barrier metal over the via and the trench;
removing the barrier metal from a bottom surface of the via and removing a part of the lower wiring exposed from the bottom surface of the via, with the barrier metal remaining on a bottom surface of the trench; and
depositing a copper film so as to fill the removed part of the lower wiring, the via, and the trench.

16. The method of manufacturing the semiconductor device according to claim 15, wherein one of a resputtering process and an etching process is used to remove the barrier metal from the via forming area.

17. The method of manufacturing the semiconductor device according to claim 16, wherein argon gas is used for the resputtering process.

18. The method of manufacturing the semiconductor device according to claim 16, wherein halogen-containing gas is used for the etching process.

19. The method of manufacturing the semiconductor device according to claim 15, wherein one of a resputtering process and an etching process is used to remove the barrier metal from the bottom surface of the via and to remove the part of the lower wiring exposed from the bottom surface of the via.

20. The method of manufacturing the semiconductor device according to claim 19, wherein argon gas is used for the resputtering process.

21. The method of manufacturing the semiconductor device according to claim 19, wherein halogen-containing gas is used for the etching process.
